(19) United States
(12) Patent Application Publication
(10) Pub. No.: US 2008/0017114 A1
(43) Pub. Date: Jan. 24, 2008

(54) HEAT TREATMENT APPARATUS OF LIGHT EMISSION TYPE

(76) Inventors: Jun WATANABE, Kyoto (JP); Toru SATO, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/778,984

(22) Filed: Jul. 17, 2007

(30) Foreign Application Priority Data
Jul. 20, 2006 (JP) 2006-198150

(51) Int. Cl. C23C 16/00

(52) U.S. Cl. 118/725; 29/25.01

(57) ABSTRACT

Nitrogen gas is exhausted from a plurality of gas outlets formed in a relatively upper part of a chamber side portion. The gas outlets are configured such that gas exhaust directions as viewed from the gas outlets are deviated at an equal angle from a central axis that passes through the center of a chamber in a vertical direction. The atmosphere in the chamber is exhausted from a bottom opening formed in a central portion of the bottom surface of the chamber. This produces such a tornado-like flow of nitrogen gas as directing from a relatively upper part of the chamber side portion to the central portion of the bottom surface of the chamber. In this condition, a flash of light is emitted with no semiconductor wafer transported into the chamber, whereby particles in the chamber are scattered and exhausted outside along with the flow of nitrogen gas.

### BACKGROUND OF THE INVENTION

1. Field of the Invention

The present invention relates to a heat treatment apparatus for exposing a substrate including a semiconductor wafer, a glass substrate for a liquid crystal display device and the like to a flash of light to heat-treat the substrate.

2. Description of the Background Art

Conventionally, a lamp annealer employing a halogen lamp has been typically used in the step of activating ions in a semiconductor wafer after ion implantation. Such a lamp annealer carries out the activation of ions in the semiconductor wafer by heating (or annealing) the semiconductor wafer to a temperature of, for example, about 1000° C. to about 1100° C. Such a heat treatment apparatus utilizes the energy of light emitted from the halogen lamp to raise the temperature of a substrate at a rate of about hundreds of degrees per second.

In recent years, with the increasing degree of integration of semiconductor devices, it has been desired to provide a shallower junction as the gate length decreases. It has turned out, however, that even the execution of the process of activating ions in a semiconductor wafer by the use of the above-mentioned lamp annealer which raises the temperature of the semiconductor wafer at a rate of about hundreds of degrees per second produces a phenomenon in which the ions of boron, phosphorus and the like implanted in the semiconductor wafer are diffused deeply by heat. The occurrence of such a phenomenon causes the depth of the junction to exceed a required level, giving rise to an apprehension about a hindrance to good device formation.

To solve the problem, there has been proposed a technique for exposing the surface of a semiconductor wafer to a flash of light by using a xenon flash lamp and the like to raise the temperature of only the surface of the semiconductor wafer implanted with ions in an extremely short time (several milliseconds or less). The xenon flash lamp has a spectral distribution of radiation ranging from ultraviolet to near-infrared regions. The wavelength of light emitted from the xenon flash lamp is shorter than that of light emitted from the conventional halogen lamp, and approximately coincides with a basic absorption band of a silicon semiconductor wafer. It is therefore possible to rapidly raise the temperature of the semiconductor wafer, with a small amount of light transmitted through the semiconductor wafer, when the semiconductor wafer is exposed to a flash of light emitted from the xenon flash lamp. Also, it has turned out that a flash of light emitted in an extremely short time of several milliseconds or less can achieve a selective temperature rise only near the surface of the semiconductor wafer. Therefore, the temperature rise in an extremely short time by using the xenon flash lamp allows the execution of only the ion activation without deeply diffusing the ions.

With increasing degree of integration of semiconductor devices, the demand to prevent particle deposition and metal contamination on semiconductor wafers has also become stronger with each passing year. However, a heat treatment apparatus employing a xenon flash lamp may cause breakage of semiconductor wafers due to momentary exposure of the semiconductor wafers to a flash of light with enormous energy during flash heating. If a semiconductor wafer is cracked and broken, a large amount of particles resulting from broken pieces of the semiconductor wafer itself, damages to a peripheral structure and the like are produced in a chamber. At the occurrence of breakage of a semiconductor wafer, the chamber is of course opened for maintenance such as collecting the broken pieces. However, complete removal of the produced particles is quite difficult, and opening the chamber causes new external particles to enter the chamber. If the flash heating process is performed with particles remaining in the chamber, the particles adhere to the semiconductor wafer, causing a processing failure.

To solve the problem, Japanese Patent Application Laid-open No. 2005-72291 discloses a cleaning technique for lighting xenon flash lamps while producing a flow of nitrogen gas in a chamber, thereby to cause momentary expansion and contraction of gas within the chamber to scatter particles and to exhaust the scattered particles along with the flow of nitrogen gas. According to this technique, lighting xenon flash lamps only a predetermined number of times at regular intervals while producing a flow of nitrogen gas in a chamber enables easy removal of particles in the chamber.

However even with the use of the aforementioned cleaning technique, the conventional heat treatment apparatus necessitates a substantial number of flash lightings for particle removal because of its low efficiency of supply and exhaust in the chamber, thus taking a long time for cleaning. Prolonged cleaning is attended with heavy consumption of nitrogen gas.

Besides, the chamber structurally has formed therein an area where a flow of gas is blown into and accumulated therein (such an area is hereinafter referred to as a “gas accumulation area”). Thus, despite prolonged cleaning and heavy consumption of nitrogen gas, particles remain in the gas accumulation area.

### SUMMARY OF THE INVENTION

The present invention is intended for a heat treatment apparatus for exposing a substrate to a flash of light to heat the substrate.

According to one aspect of the present invention, the heat treatment apparatus comprises: a light source including a plurality of flash lamps; a chamber provided under the light source for receiving a substrate therein; a holding element for holding the substrate within the chamber; a plurality of gas outlets provided in a side wall surface of the chamber, the plurality of gas outlets being formed such that gas exhaust directions as viewed from the plurality of gas outlets are deviated at an equal angle from a central axis that passes through the center of the chamber in a vertical direction; a gas supply for supplying an inert gas to the plurality of gas outlets; an exhaust port provided in the vicinity of a central portion of a bottom surface of the chamber; and an exhaust element for exhausting gas in the chamber through the exhaust port.

The heat treatment apparatus is capable of producing a tornado-like flow (spiral flow) of inert gas from the plurality of gas outlets to an exhaust port provided in the vicinity of the center of the bottom surface of the chamber. This eliminates a gas accumulation area inside the chamber to improve the efficiency of supply and exhaust and thereby to allow particles in the chamber to be removed in a short time with reliability.

Preferably, a corner of the inner wall surface of the chamber is rounded.

The heat treatment apparatus is capable of readily producing a tornado-like flow of gas from the plurality of gas outlets to the exhaust port.

According to another aspect of the present invention, the heat treatment apparatus comprises: a light source including a plurality of flash lamps; a chamber provided under the light source for receiving a substrate therein; a holding element for holding the substrate within the chamber; a plurality of gas outlets provided in a side wall surface of the chamber, the plurality of gas outlets being formed such that an inert gas discharged from the plurality of gas outlets forms a tornado-like flow in the chamber; a gas supply for supplying an inert gas to the plurality of gas outlets; an exhaust port provided in the vicinity of a central portion of a bottom surface of the chamber; and an exhaust element for exhausting gas in the chamber through the exhaust port.

The heat treatment apparatus is capable of eliminating a gas accumulation area inside the chamber to improve the efficiency of supply and exhaust and thereby to allow particles in the chamber to be removed in a short time with reliability.

It is therefore an object of the present invention to provide a heat treatment apparatus capable of removing particles in a chamber in a short time with reliability.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a side sectional view showing the construction of a heat treatment apparatus according to the present invention;

FIG. 2 is a partially enlarged sectional view of a gas supply mechanism for supplying gas into a chamber;

FIG. 3 is an external perspective view of a ring;

FIG. 4 is a schematic plan view of a chamber taken along a horizontal plane in the positions of gas outlets;

FIG. 5 is a side sectional view showing the construction of the heat treatment apparatus in FIG. 1;

FIG. 6 is a plan view of a hot plate;

FIG. 7 is a flowchart showing a procedure of cleaning process in a chamber; and

FIG. 8 shows a tornado-like flow produced in a chamber.

### DESCRIPTION OF THE PREFERRED EMBODIMENTS

A preferred embodiment according to the present invention will now be described in detail with reference to the drawings.

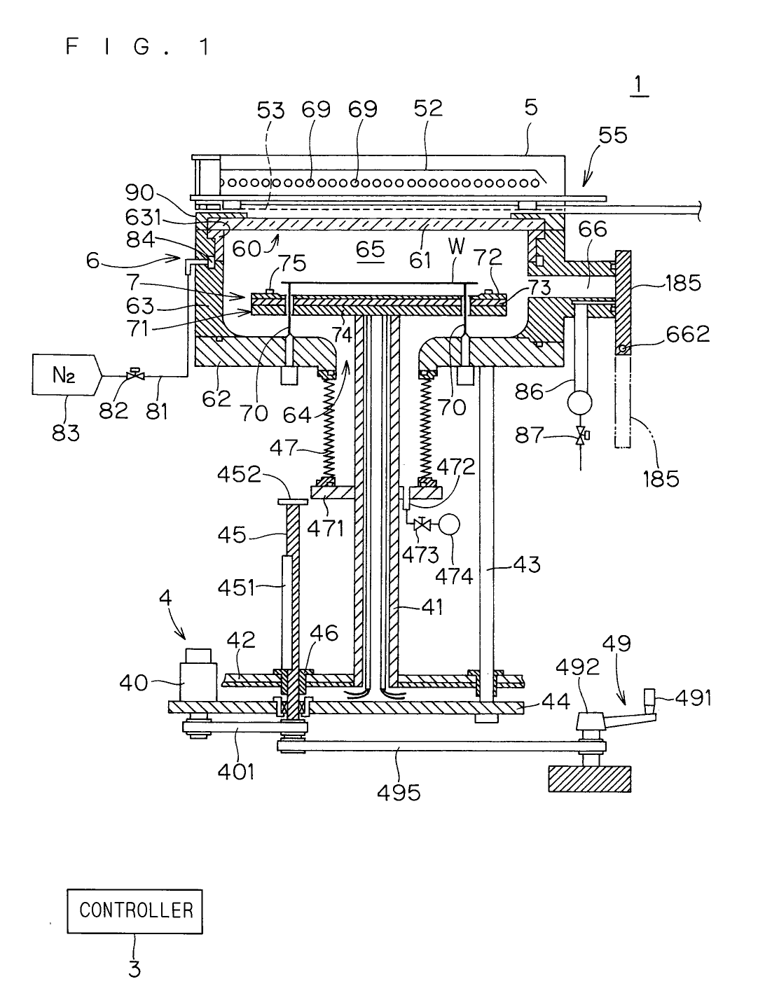

FIG. 1 is a side sectional view showing the construction of a heat treatment apparatus 1 according to the present invention. The heat treatment apparatus 1 is a flash lamp annealer for exposing a semiconductor wafer W serving as a substrate to a flash of light to heat the semiconductor wafer W.

The heat treatment apparatus 1 comprises a chamber 6 of a generally cylindrical configuration for receiving a semiconductor wafer W therein. The chamber 6 includes a chamber side portion 63 having an inner wall of a generally cylindrical configuration, and a chamber bottom portion 62 for covering a bottom portion of the chamber side portion 63. A space surrounded by the chamber side portion 63 and the chamber bottom portion 62 is defined as a heat treatment space 65. A top opening 60 is formed over the heat treatment space 65.

The heat treatment apparatus 1 further comprises: a light-transmittable plate 61 serving as a closure member mounted in the top opening 60 for closing the top opening 60; a holding part 7 of a generally disk-shaped configuration for preheating a semiconductor wafer W while holding the semiconductor wafer W within the chamber 6; a holding part elevating mechanism 4 for moving the holding part 7 upwardly and downwardly relative to the chamber bottom portion 62 serving as the bottom surface of the chamber 6; a light emitting part 5 for directing light through the light-transmittable plate 61 onto the semiconductor wafer W held by the holding part 7 to heat the semiconductor wafer W; and a controller 3 for controlling the above-mentioned components to perform heat treatment.

The chamber 6 is provided under the light emitting part 5. The light-transmittable plate 61 provided in an upper portion of the chamber 6 is a disk-shaped member made of, for example, quartz, and allows light emitted from the light emitting part 5 to travel therethrough into the heat treatment space 65. The chamber bottom portion 62 and the chamber side portion 63 which constitute the main body of the chamber 6 are made of a metal material having high strength and high heat resistance such as stainless steel and the like. A ring 631 provided in an upper portion of the inner side surface of the chamber side portion 63 is made of an aluminum (Al) alloy and the like having greater durability against degradation resulting from exposure to flash light than stainless steel.

An O-ring (not shown) provides a seal between the light-transmittable plate 61 and the chamber side portion 63 so as to maintain the hermeticity of the heat treatment space 65. Specifically, an annular groove is formed in the upper end of the chamber side portion 63 of the generally cylindrical configuration, and the O-ring is fitted in the annular groove and pressed down by the light-transmittable plate 61. For the purpose of holding the O-ring in intimate contact between a lower peripheral portion of the light-transmittable plate 61 and the chamber side portion 63, a clamp ring 90 abuts against an upper peripheral portion of the light-transmittable plate 61 and is secured to the chamber side portion 63 by screws, thereby forcing the light-transmittable plate 61 against the O-ring.

The chamber bottom portion 62 is provided with a plurality of (in this preferred embodiment, three) upright support pins 70 extending through the holding part 7 for supporting the lower surface (a surface opposite from a surface onto which light is directed from the light emitting part 5) of the semiconductor wafer W. The support pins 70 are made of, for example, quartz, and are easy to replace because the support pins 70 are fixed externally of the chamber 6.

The chamber side portion 63 includes a transport opening 66 for the transport of the semiconductor wafer W therethrough into and out of the chamber 6. The transport opening 66 is openable and closable by a gate valve 185 pivoting about an axis 662. An inlet passage 81 for introducing a processing gas (for example, an inert gas including nitrogen (N₂) gas, helium (He) gas, argon (Ar) gas and the like, or oxygen (O₂) gas and the like) into the heat treatment space 65 is formed on the opposite side of the chamber side portion 63 from the transport opening 66. The inlet passage 81 has one end connected through a valve 82 to a gas supply 83, and the other end connected in communication with a gas inlet buffer 84 formed inside the chamber side portion 63.

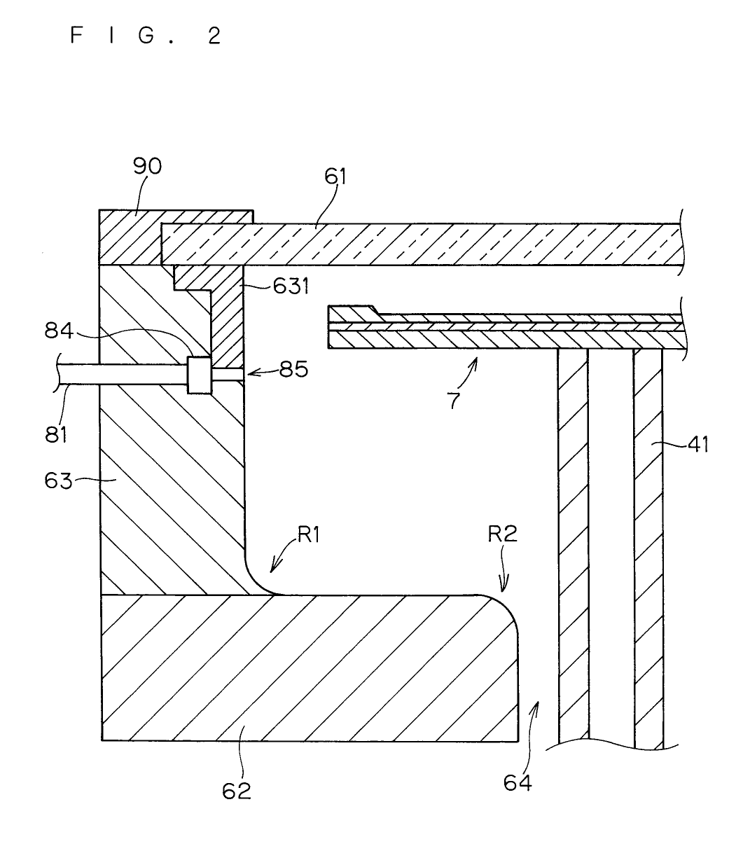

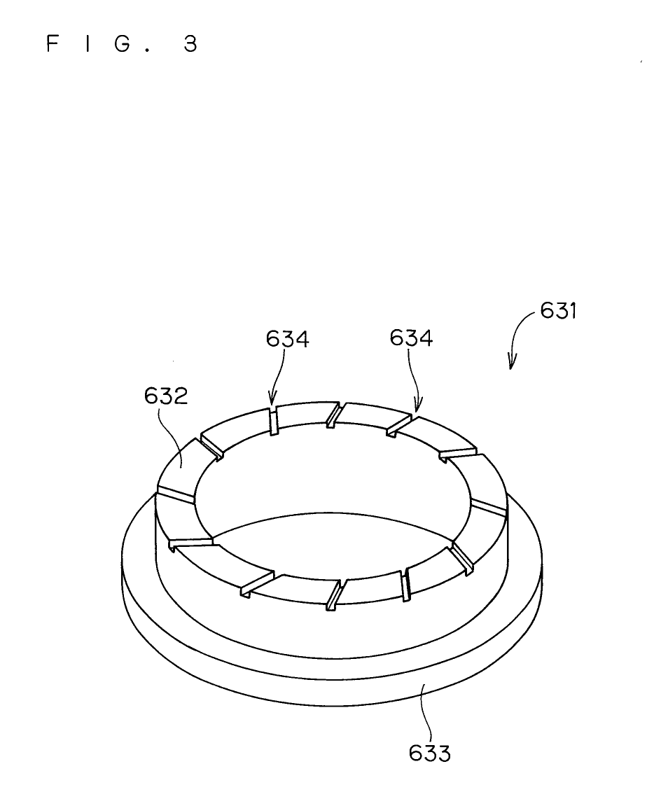

FIG. 2 is a partially enlarged sectional view of a gas supply mechanism for supplying gas into the chamber 6. The support pins 70 are not shown in this figure. As described above, the ring 631 of an aluminum alloy having high flash resistance is fitted in the upper portion of the inner side surface of the chamber side portion 63 made of stainless steel. FIG. 3 is an external perspective view of the ring 631. The ring 631 is an annular member consisting of a tube 632 and a flange 633 formed at the end of the tube 632. The tube 632 has a plurality of (in this preferred embodiment, twelve) slits 634 formed in its end face opposite to the flange 633. The twelve slits 643 are equally spaced 30° apart from each other circumferentially of the end face of the tube 632. As shown in this figure, the plurality of slits 634 are formed such that the longitudinal directions of the slits 634 are deviated at an equal angle from the center of the ring 631. For the insertion of the ring 631 in FIG. 3 into the chamber side portion 63, the end of the ring 631 on the side where the slits 634 are formed is directed downward.

Fitting the ring 631 as shown in FIG. 3 in the chamber side portion 63 produces gas outlets 85 which are surrounded by the slits 634 and the end face of the chamber side portion 63 as shown in FIG. 2. Since the ring 631 has the twelve slits 634 formed therein in this preferred embodiment, twelve gas outlets 85 are formed in the side wall surface of the chamber 6. The twelve gas outlets 85 are equally spaced (i.e., 30° apart from each other) circumferentially of the cylindrical wall of the chamber side portion 63 at the same level. In this preferred embodiment, the gas exhaust directions from the respective twelve gas outlets 85 are approximately horizontal. The twelve gas outlets 85 are in communication with the gas inlet buffer 84.

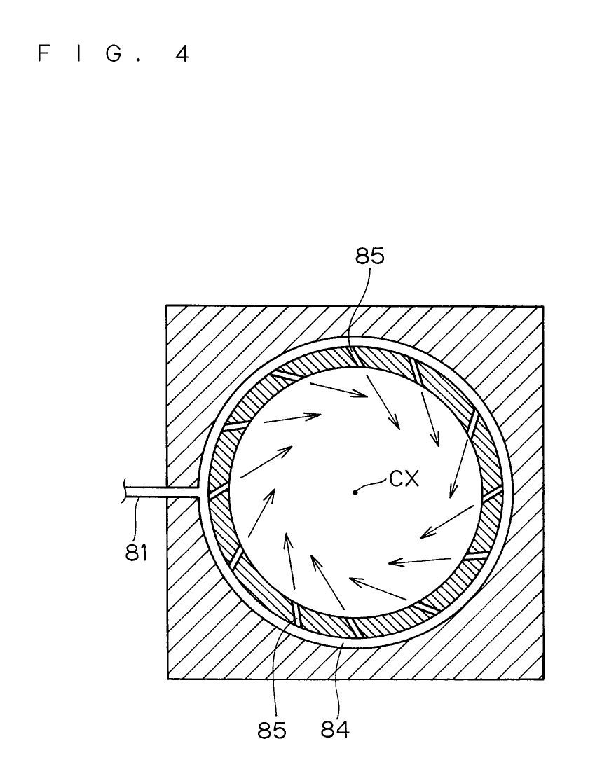

FIG. 4 is a schematic plan view of the chamber 6 taken along a horizontal plane in the positions of the gas outlets 85. As shown, the gas inlet buffer 84 connected with the inlet passage 81 is an annular space. The twelve gas outlets 85 are provided in communication with the gas inlet buffer 84. Thus, gas supplied from the gas supply 83 through the inlet passage 81, with the valve 82 open, flows once into the gas inlet buffer 84 and then is exhausted from the respective twelve gas outlets 85 into the chamber 6.

The gas outlets 85 are formed such that the gas exhaust directions from the twelve gas outlets 85 are deviated at an equal angle (leftward as viewed from above the plane of the drawing) from a central axis CX that passes through the center of the chamber 6 in a vertical direction. That is, as shown in FIG. 4, gas is exhausted from the gas outlets 85 in directions that are deviated at an equal angle from the central axis CX, and flows into the chamber 6.

Referring back to FIG. 1, the holding part elevating mechanism 4 shown in FIG. 1 includes a shaft 41 of a generally cylindrical configuration, a movable plate 42, guide members 43 (in this preferred embodiment, three guide members 43 are provided around the shaft 41), a fixed plate 44, a ball screw 45, a nut 46, and a motor 40. The chamber bottom portion 62 serving as the bottom portion of the chamber 6 is formed with a bottom opening 64 of a generally circular configuration having a diameter smaller than that of the holding part 7. The shaft 41 made of stainless steel is inserted through the bottom opening 64 and connected to the lower surface of the holding part 7 (a hot plate 71 of the holding part 7 in a strict sense) to support the holding part 7. In this preferred embodiment, the shaft 41 coincides with the aforementioned central axis CX of the chamber 6.

The nut 46 for threaded engagement with the ball screw 45 is fixed to the movable plate 42. The movable plate 42 is slidably guided by the guide member 43 fixed to the chamber bottom portion 62 and extending downwardly therefrom, and is vertically movable. The movable plate 42 is coupled through the shaft 41 to the holding part 7.

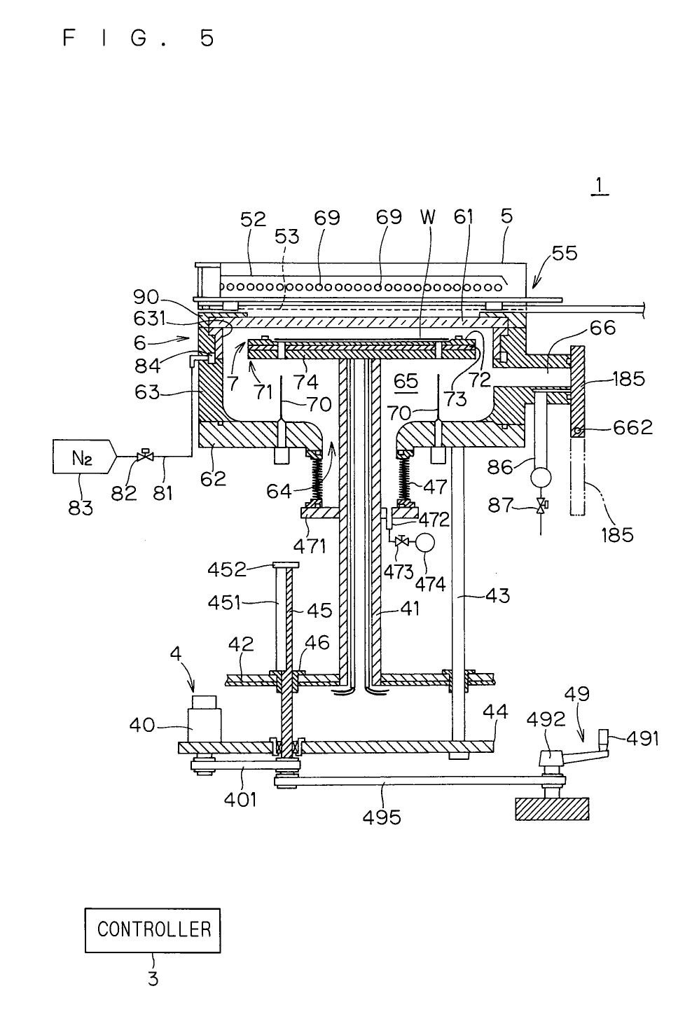

The motor 40 is provided on the fixed plate 44 mounted to the lower end portion of the guide member 43, and is connected to the ball screw 45 through a timing belt 401. When the holding part elevating mechanism 4 moves the holding part 7 upwardly and downwardly, the motor 40 serving as a driver rotates the ball screw 45 under the control of the controller 3 to move the movable plate 42 fixed to the nut 46 vertically along the guide member 43. As a result, the shaft 41 fixed to the movable plate 42 moves vertically, whereby the holding part 7 connected to the shaft 41 smoothly moves upwardly and downwardly between a transfer position shown in FIG. 1 in which the semiconductor wafer W is transferred and a heat treatment position shown in FIG. 5 in which the semiconductor wafer W is heat-treated.

An upright mechanical stopper 451 of a generally semi-cylindrical configuration (obtained by cutting a cylinder in half in a longitudinal direction) is provided on the upper surface of the movable plate 42 so as to extend along the ball screw 45. If the movable plate 42 is to move upwardly beyond a predetermined upper limit because of any anomaly, the upper end of the mechanical stopper 451 strikes an end plate 452 provided at an end portion of the ball screw 45, whereby the abnormal upward movement of the movable plate 42 is prevented. This avoids the upward movement of the holding part 7 above a predetermined position lying under the light-transmittable plate 61, to thereby prevent a collision between the holding part 7 and the light-transmittable plate 61.

The holding part elevating mechanism 4 further includes a manual elevating part 49 for manually moving the holding part 7 upwardly and downwardly during the maintenance of the interior of the chamber 6. The manual elevating part 49 has a handle 491 and a rotary shaft 492. Rotating the rotary shaft 492 by means of the handle 491 causes the rotation of the ball screw 45 connected through a timing belt 495 to the rotary shaft 492, thereby moving the holding part 7 upwardly and downwardly.

An expandable/contractible bellows 47 surrounding the shaft 41 and extending downwardly from the chamber bottom portion 62 is provided under the chamber bottom portion 62, and has an upper end connected to the lower surface of the chamber bottom portion 62. The bellows 47 has a lower end mounted to a bellows lower end plate 471. The bellows lower end plate 471 is screw-held and mounted to the shaft 41 by a collar member (not shown). The bellows 47 contracts when the holding part elevating mechanism 4 moves the holding part 7 upwardly relative to the chamber bottom portion 62, and expands when the holding part elevating mechanism 4 moves the holding part 7 downwardly. When the holding part 7 moves upwardly and downwardly, the bellows 47 contracts and expands to maintain the heat treatment space 65 hermetically sealed.

The bellows lower end plate 471 is provided with a gas exhaust port 472 for exhausting gas in the heat treatment space 65. Since the shaft 41 coincides with the central axis CX in this preferred embodiment, the gas exhaust port 472 is provided in the vicinity of the center of the bottom surface of the chamber 6. The gas exhaust port 472 is in communication with an exhaust pump 474 through a valve 473. When the valve 473 is opened upon actuation of the exhaust pump 474, gas in the chamber 6 is exhausted from the bottom opening 64 through the gas exhaust port 472 out of the chamber. The transport opening 66 is also provided with an outlet passage 86 for exhausting gas in the heat treatment space 65, which is connected through the valve 87 to an exhaust mechanism not shown. This exhaust mechanism and the above exhaust pump 474 may be a common unit.

The holding part 7 includes the hot plate (heating plate) 71 for preheating (or assist-heating) the semiconductor wafer W, and a susceptor 72 provided on the upper surface (a surface on which the holding part 7 holds the semiconductor wafer W) of the hot plate 71. The shaft 41 for moving the holding part 7 upwardly and downwardly as mentioned above is connected to the lower surface of the holding part 7. The susceptor 72 is made of quartz (or may be made of aluminum nitride (AlN) or the like). Pins 75 for preventing the semiconductor wafer W from shifting out of place are mounted on the upper surface of the susceptor 72. The susceptor 72 is provided on the hot plate 71, with the lower surface of the susceptor 72 in face-to-face contact with the upper surface of the hot plate 71. Thus, the susceptor 72 diffuses heat energy from the hot plate 71 to transfer the heat energy to the semiconductor wafer W placed on the upper surface of the susceptor 72, and is removable from the hot plate 71 for cleaning during maintenance.

The hot plate 71 includes an upper plate 73 and a lower plate 74 both made of stainless steel. Resistance heating wires such as nichrome wires for heating the hot plate 71 are provided between the upper plate 73 and the lower plate 74, and an electrically conductive brazing metal containing nickel (Ni) fills the space between the upper plate 73 and the lower plate 74 to seal the resistance heating wires therewith. The upper plate 73 and the lower plate 74 have brazed or soldered ends.

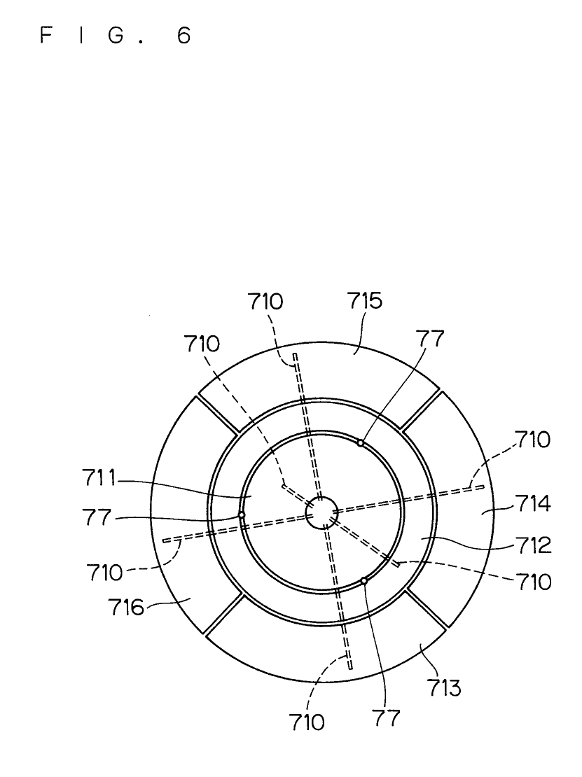

FIG. 6 is a plan view of the hot plate 71. As shown in FIG. 6, the hot plate 71 has a circular zone 711 and an annular zone 712 arranged in concentric relation with each other and positioned in a central portion of a region opposed to the semiconductor wafer W held by the holding part 7, and four zones 713 to 716 into which a substantially annular region surrounding the zone 712 is circumferentially equally divided. Slight gaps are formed between these zones 711 to 716. The hot plate 71 is provided with three through holes 77 receiving the respective support pins 70 therethrough and circumferentially spaced 120° apart from each other in a gap between the zones 711 and 712.

In the six zones 711 to 716, the resistance heating wires independent of each other are disposed so as to make a circuit to form heaters, respectively. The heaters incorporated in the respective zones 711 to 716 individually heat the respective zones. The semiconductor wafer W held by the holding part 7 is heated by the heaters incorporated in the six zones 711 to 716. A sensor 710 for measuring the temperature of each zone by using a thermocouple is provided in each of the zones 711 to 716. The sensors 710 pass through the interior of the generally cylindrical shaft 41 and are connected to the controller 3.

For heating the hot plate 71, the controller 3 controls the amount of power supply to the resistance heating wires provided in the respective zones 711 to 716 so that the temperatures of the six zones 711 to 716 measured by the sensors 710 reach a previously set predetermined temperature. The temperature control in each zone by the controller 3 is PID (Proportional, Integral, Derivative) control. In the hot plate 71, the temperatures of the respective zones 711 to 716 are continually measured until the heat treatment of the semiconductor wafer W (the heat treatment of all semiconductor wafers W when the plurality of semiconductor wafers W are successively heat-treated) is completed, and the amounts of power supply to the resistance heating wires provided in the respective zones 711 to 716 are individually controlled, that is, the temperatures of the heaters incorporated in the respective zones 711 to 716 are individually controlled, whereby the temperatures of the respective zones 711 to 716 are maintained at the set temperature. The set temperature for the zones 711 to 716 may be changed by an individually set offset value from a reference temperature.

The resistance heating wires provided in the six zones 711 to 716 are connected through power lines passing through the interior of the shaft 41 to a power source (not shown). The power lines extending from the power source to the zones 711 to 716 are disposed inside a stainless tube filled with an insulator of magnesia (magnesium oxide) or the like so as to be electrically insulated from each other. The interior of the shaft 41 is open to the atmosphere.

The light emitting part 5 shown in FIG. 1 is a light source including a plurality of (in this preferred embodiment, 30) xenon flash lamps (referred to simply as “flash lamps” hereinafter) 69, and a reflector 52. The plurality of flash lamps 69 each of which is a rod-like lamp having an elongated cylindrical configuration are arranged in a plane so that the longitudinal directions of the respective flash lamps 69 are in parallel with each other along a major surface of the semiconductor wafer W held by the holding part 7. The reflector 52 is provided over the plurality of flash lamps 69 to cover all of the flash lamps 69. The surface of the reflector 52 is roughened by abrasive blasting to produce a stain finish thereon. A light diffusion plate 53 (or a diffuser) is made of quartz glass having a surface subjected to a light diffusion process, and is provided on the lower surface side of the light emitting part 5, with a predetermined spacing held between the light diffusion plate 53 and the light-transmittable plate 61. The heat treatment apparatus 1 further comprises an emitting-part movement mechanism 55 for moving the light emitting part 5 upwardly relative to the chamber 6 and then for sliding the light emitting part 5 in a horizontal direction during maintenance.

Each of the xenon flash lamps 69 includes a glass tube containing xenon gas sealed therein and having positive and negative electrodes provided on opposite ends thereof and connected to a capacitor, and a trigger electrode wound on the outer peripheral surface of the glass tube. Because the xenon gas is electrically insulative, no current flows in the glass tube in a normal state. However, if a high voltage is applied to the trigger electrode to produce an electrical breakdown, electricity stored in the capacitor flows momentarily in the glass tube, and the Joule heat evolved at this time heats the xenon gas to cause light emission. The xenon flash lamps 69 have the property of being capable of emitting more intense light than a light source that stays lit continuously because previously stored electrostatic energy is converted into an ultrashort light pulse ranging from 0.1 millisecond to 10 milliseconds.

The heat treatment apparatus 1 according to this preferred embodiment includes various cooling structures (not shown) to prevent an excessive temperature rise in the chamber 6 and the light emitting part 5 because of the heat energy generated from the flash lamps 69 and the hot plate 71 during the heat treatment of the semiconductor wafer W. As an example, the chamber side portion 63 and the chamber bottom portion 62 of the chamber 6 are provided with a water cooling tube, and the light emitting part 5 is provided with a supply pipe for supplying a gas to the interior thereof and an exhaust pipe with a silencer to form an air cooling structure. Compressed air is supplied to the gap between the light-transmittable plate 61 and the light emitting part 5 (the light diffusion plate 53) to cool down the light emitting part 5 and the light-transmittable plate 61 and to remove organic materials and the like present in the gap therefrom to suppress the deposition of the organic materials and the like to the light diffusion plate 53 and the light-transmittable plate 61 during the heat treatment.

Next, the operations of the heat treatment apparatus 1 will be described. First, a procedure of cleaning the interior of the chamber 6 will be described. The cleaning of the chamber 6 is performed at regular maintenance of the heat treatment apparatus 1, at startup of the apparatus, upon breakage of the semiconductor wafer W being processed, or the like. “Cleaning”, as used herein, is the process of removing microscopic particles remaining in the chamber 6 after cleaning up of broken pieces of wafers and the like is completed.

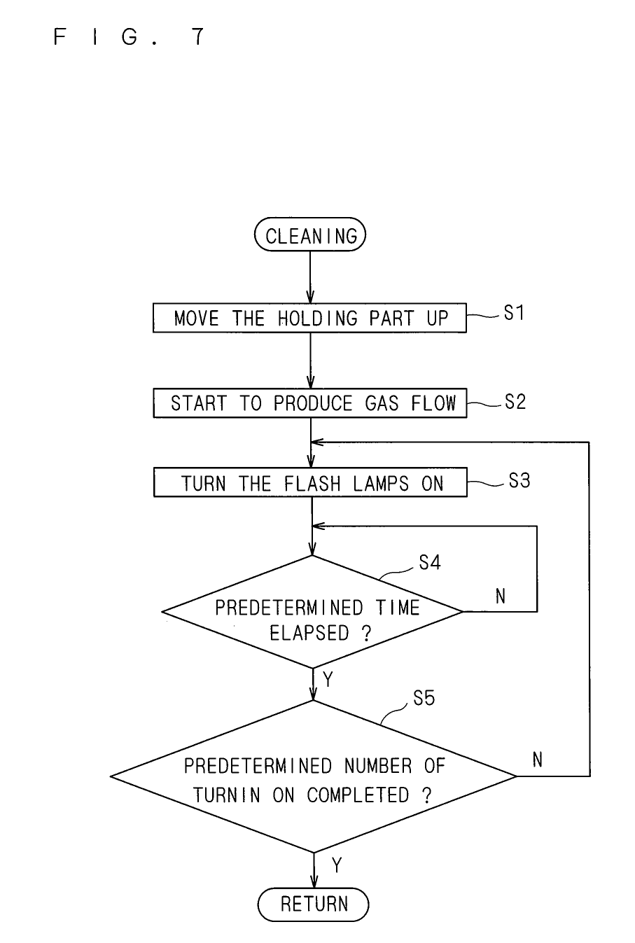

FIG. 7 is a flowchart showing a procedure of cleaning process in the chamber. The process in FIG. 7 is achieved by actuation of each mechanism such as the holding part movement mechanism 4 and the light emitting part 5 under the control of the controller 3.

For the cleaning process, first of all, the transport of the semiconductor wafer W to be treated is inhibited and the holding part 7 is moved upward to the heat treatment position in FIG. 5 (step S1). Since no semiconductor wafer W is transported in the chamber 6 during the cleaning process, the holding part 7 is moved upward to the heat treatment position with nothing placed thereon. The heaters in the hot plate 71 are OFF so that the hot plate 71 remains unheated. The vertical position of the holding part 7 shown in FIG. 2 corresponds to the heat treatment position. The holding part 7 moved upward to the heat treatment position is slightly above the gas outlets 85.

After the holding part 7 moves upward to the heat treatment position, a flow of nitrogen gas is produced in the chamber 6 (step S2). Specifically, with the valve 82 open, nitrogen gas is supplied from the gas supply 83 through the inlet passage 81 to the gas inlet buffer 84, and is exhausted from the twelve gas outlets 85 into the chamber 6. Since nitrogen gas once flows into the gas inlet buffer 84 and is then exhausted from the twelve gas outlets 85, the amount of exhaust gas from each of the gas outlets 85 is approximately uniform.

With the supply of nitrogen gas, the valve 473 is opened upon actuation of the exhaust pump 474, whereby the atmosphere in the chamber 6 is exhausted from the bottom opening 64 through the gas exhaust port 472. At this time, the valve 87 may also be opened for exhaust from the outlet passage 86.

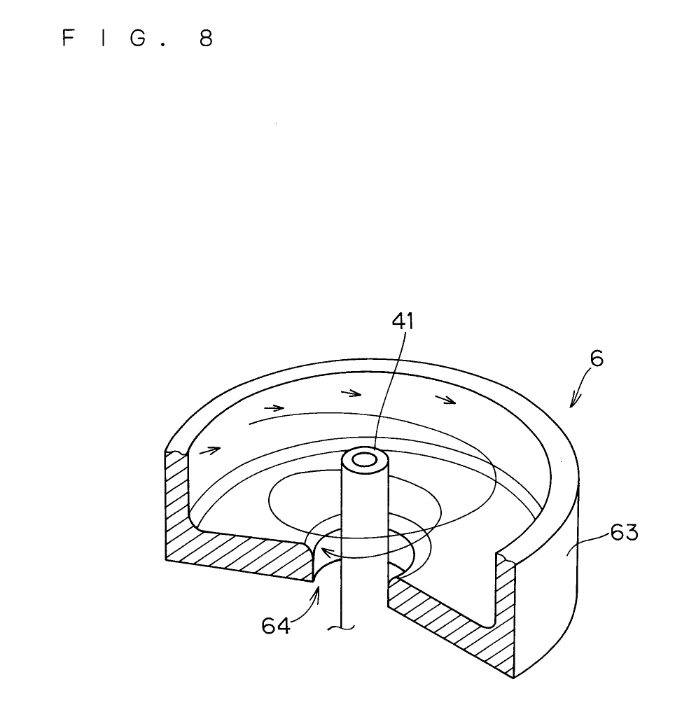

This produces in the chamber 6 a gas flow, along which the nitrogen gas exhausted from the gas outlets 85 is exhausted through the bottom opening 64 from the gas exhaust port 472. Since in this preferred embodiment the twelve gas outlets 85 are configured such that their gas exhaust directions are deviated at an equal angle from the central axis CX passing through the center of the chamber 6 in the vertical direction, nitrogen gas from the gas outlets 85 is exhausted in directions that are deviated at an equal angle from the central axis CX, and flows into the chamber 6 (see FIG. 4). Consequently, as shown in FIG. 8, the nitrogen gas exhausted from the gas outlets 85 forms a tornado-like (spiral) flow in the chamber 6. Since the gas exhaust port 472 provided in the vicinity of the center of the bottom surface of the chamber 6 exhausts gas in this preferred embodiment, such a tornado-like flow is produced as directing from relatively an upper part of the chamber side portion 63 toward a central portion of the chamber bottom surface. This tornado-like flow is produced to encircle the central axis CX (which coincides with the shaft 41 in this example) of the chamber 6, with its diameter decreasing toward the chamber bottom.

With the tornado-like flow of nitrogen gas produced in the chamber 6, the flash lamps 69 are turned on to emit a flash of light toward the interior of the chamber 6 (step S3). This emission of the flash of light is performed with no semiconductor wafer W held on the holding part 7 and thus is called “ghost flash.” The length of time during which the flash lamps 69 are ON ranges from about 0.1 millisecond to about 10 milliseconds. Since in the flash lamps 69 previously stored electrostatic energy is converted into such an ultrashort light pulse, an extremely intense flash of light is emitted toward the interior of the chamber 6. The emission of the flash of light from the flash lamps 69 heats gas and structural components in the chamber 6, causing momentary expansion and contraction of the gas in the chamber 6, whereby particles are brown up to scatter in the chamber 6. Particles are prone to be deposited particularly on the upper surface of the chamber bottom portion 62. However, emitting the flash of light with the heating plate 7 moved up to the heat treatment position as in this preferred embodiment makes it easy to blow up such particles that are deposited on the bottom portion.

The scattering particles are carried outside the chamber 6 by the tornado-like flow of nitrogen gas. According to this preferred embodiment, since the exhaust is conducted along with the production of the tornado-like flow of nitrogen gas in the chamber 6, it is possible to circulate the flow of nitrogen gas thoroughly inside the chamber 6 during exhaust. This improves the efficiency of supply and exhaust, thereby allowing the scattering particles inside the chamber 6 to be exhausted out of the chamber in a considerably shorter time than conventional methods. Besides, since the so-called gas accumulation area becomes hard to be formed in the chamber 6, the scattering particles in the chamber 6 can be removed with reliability.

After turn-on of the flash lamps 69, the controller 3 determines whether a predetermined length of time has elapsed (step S4). That is, after emission of a single flash of light, the particle removal is performed for a predetermined period of time. During the lapse of this predetermined time period, such a tornado-like flow of nitrogen gas as directing from the gas outlets 85 to a central portion of the chamber bottom surface continues to be produced.

Although a considerable amount of particles is removed outside the chamber 6 after a lapse of the predetermined time period, some particles are deposited again on the chamber bottom portion 62. Next, the controller 3 determines whether the flash lamps 69 have been turned on a predetermined number of times (step S5). If the number of times that the flash lamps 69 were turned on does not reach a predetermined number of times, the process returns to step S3 to turn on the flash lamps 69 again. More specifically, deposited particles are again blown up to scatter by the emission of a flash of light caused by the turn-on of the flash lamps 69, and the scattering particles are removed outside the chamber 6 by the tornado-like flow of nitrogen gas. On the other hand, if the number of times that the flash lamps 69 were turned on reaches the predetermined number of times, the cleaning process is completed.

In this fashion, since the exhaust is conducted along with the production of the tornado-like flow of nitrogen gas in the chamber 6, it is possible to improve the efficiency of supply and exhaust and thereby to remove particles in the chamber 6 in a considerably shorter time than conventional methods. Removing particles in the chamber 6 in a short time shortens the time of apparatus start-up and the time of maintenance as well as cuts down the number of ghost flashes (step S3) and the consumption of nitrogen gas. Besides, since the so-called gas accumulation area is hard to be formed in the chamber 6, particles in the chamber 6 can be removed in a short time with reliability.

The heat treatment apparatus 1 according to this preferred embodiment also performs rounding of corners of the inner wall of the chamber 6 where the tornado-like flow of nitrogen gas passes by. More specifically, as shown in FIG. 2, a corner R1 along the bottom surface edge of the inner wall of the chamber 6 is rounded. The heat treatment apparatus 1 also rounds a corner R2 along the edge of the bottom opening 64 which is formed in the bottom surface of the chamber 6 for access to the gas exhaust port 472. This allows easy production of the tornado-like flow of nitrogen gas inside the chamber 6 as well as allows smooth circulation of that flow in the chamber 6. Consequently, it becomes possible to remove particles in the chamber 6 in a shorter time with reliability.

Next, a procedure for treating the semiconductor wafer W in the heat treatment apparatus 1 will be briefly described. The semiconductor wafer W to be treated herein is a semiconductor substrate doped with impurities by an ion implantation process. The activation of the implanted impurities is achieved by the heat treatment of the heat treatment apparatus 1.

First, the holding part 7 is placed in a position (transfer position) close to the chamber bottom portion 62 as shown in FIG. 1. When the holding part 7 is in the transfer position, the upper ends of the support pins 70 protrude through the holding part 7 upwardly out of the holding part 7.

Next, the valve 82 and the valve 473 (valve 87 as necessary) are opened to introduce nitrogen gas into the heat treatment space 65 of the chamber 6. Subsequently, the transport opening 66 is opened, and a transport robot outside the apparatus transports the ion-implanted semiconductor wafer W through the transport opening 66 into the chamber 6 and places the semiconductor wafer W onto the plurality of support pins 70. In each of the steps described below, nitrogen gas is constantly being supplied into and exhausted from the chamber 6.

After the semiconductor wafer W is transported into the chamber 6, the gate valve 185 closes the transport opening 66. Next, as shown in FIG. 5, the holding part elevating mechanism 4 moves the holding part 7 upwardly to a position (heat treatment position) close to the light-transmittable plate 61. Then, the semiconductor wafer W is transferred from the support pins 70 to the susceptor 72 of the holding part 7, and is placed and held on the upper surface of the susceptor 72.

Each of the six zones 711 to 716 of the hot plate 71 is already heated up to a predetermined temperature by the resistance heating wire individually provided within each of the zones 711 to 716 (between the upper plate 73 and the lower plate 74). The holding part 7 is moved upwardly to the heat treatment position to bring the semiconductor wafer W in contact with the holding part 7, whereby the semiconductor wafer W is preheated and the temperature of the semiconductor wafer W increases gradually.

Preheating the semiconductor wafer W in the heat treatment position for about 60 seconds increases the temperature of the semiconductor wafer W up to a previously set preheating temperature Ti. The preheating temperature T1 shall range from about 200° C. to about 600° C., preferably from about 350° C. to about 550° C., at which there is no apprehension that the impurities implanted in the semiconductor wafer W are diffused by heat. A distance between the holding part 7 and the light-transmittable plate 61 is adjustable to any value by controlling the amount of rotation of the motor 40 of the holding part elevating mechanism 4.

After a lapse of the preheating time of about 60 seconds, a flash of light is emitted from the light emitting part 5 toward the semiconductor wafer W under the control of the controller 3 while the holding part 7 remains in the heat treatment position. Part of the light emitted from the flash lamps 69 of the light emitting part 5 travels directly to the interior of the chamber 6. The remainder of the light is reflected by the reflector 52, and the reflected light travels to the interior of the chamber 6. Such emission of the flash of light achieves the flash heating of the semiconductor wafer W. The flash heating, which is achieved by the emission of a flash of light from the flash lamps 69, can raise the surface temperature of the semiconductor wafer W in a short time.

Specifically, the surface temperature of the semiconductor wafer W subjected to the flash heating by the emission of the flash of light from the flash lamps 69 momentarily rises to a heat treatment temperature T2 of about 1000° C. to about 1100° C. After activation of the impurities implanted in the semiconductor wafer W, the surface temperature decreases rapidly. Because of the capability of increasing and decreasing the surface temperature of the semiconductor wafer W in an extremely short time, the heat treatment apparatus 1 can achieve the activation of the impurities while suppressing the diffusion of the impurities implanted in the semiconductor wafer W due to heat (such a diffusion phenomenon is also known as a round or dull profile of the impurities implanted in the semiconductor wafer W). Because the time required for the activation of the implanted impurities is extremely short as compared with the time required for the thermal diffusion of the implanted impurities, the activation is completed in a short time ranging from about 0.1 millisecond to about 10 milliseconds during which no diffusion occurs.

Preheating the semiconductor wafer W by the holding part 7 prior to the flash heating allows the emission of the flash of light from the flash lamps 69 to rapidly increase the surface temperature of the semiconductor wafer W up to the heat treatment temperature T2.

After waiting in the heat treatment position for about 10 seconds following the completion of the flash heating, the holding part 7 is moved downwardly again to the transfer position shown in FIG. 1 by the holding part elevating mechanism 4, and the semiconductor wafer W is transferred from the holding part 7 to the support pins 70. Subsequently, the gate valve 185 opens the transport opening 66 having been closed, and the transport robot outside the apparatus transports the semiconductor wafer W placed on the support pins 70 outwardly. Thus, the flash heating process of the semiconductor wafer W in the heat treatment apparatus 1 is completed.

While the preferred embodiment according to the present invention has been described hereinabove, it is understood that various modifications and changes can be made to the described embodiment without departing from the scope of the present invention. For example, while the ring 631 having the slits 643 formed therein is fitted in the chamber side portion 63 to form the twelve gas outlets 85 according to the above-described embodiment, the present invention is not limited thereto. The gas outlets may be formed by perforating so-called circular holes in the chamber side portion 63. For easy production of a tornado-like flow while avoiding interference between the gas flow and the holding part 7, the gas outlets should preferably be formed slightly below the holding part 7 which is moved up to the heat treatment position.

The number of gas outlets 85 is not limited to twelve but may be any arbitrary number as long as a tornado-like flow of gas can be formed within the chamber 6.

The gas exhaust directions from the plurality of gas outlets 85 may be downward from the horizontal plane. This makes it easier to produce such a tornado-like flow of gas as directing from a relatively upper part of the chamber side portion 63 toward a central portion of the chamber bottom surface.

While the tornado-like flow of nitrogen gas is produced during cleaning of the interior of the chamber 6 according to the aforementioned preferred embodiment, other inert gases (e.g., argon gas) may be used to form a tornado-like flow. However, in terms of cost, the use of nitrogen gas is preferable.

While the so-called “ghost flash,” which is the emission of the flash of light with no semiconductor wafer W held on the holding part 7, is triggered during the cleaning process of the chamber 6 according to the aforementioned preferred embodiment, the ghost flash is not necessarily needed. Only forming a tornado-like flow of nitrogen gas within the chamber 6 can eliminate a gas accumulation area in the chamber to improve the efficiency of supply and exhaust and thereby to allow short-time and reliable particle removal from the chamber.

As another alternative, the plurality of gas outlets 85 may be used as gas exhaust ports exclusively for use in the cleaning process, and other gas exhaust ports whose gas exhaust directions are toward the central axis CX of the chamber 6 as in conventional methods may be provided for use in the heat treatment of the semiconductor wafer W.

Although the 30 flash lamps 69 are provided in the light emitting part 5 according to the aforementioned preferred embodiment, the present invention is not limited to this. The number of flash lamps 69 may be any arbitrary number.

The flash lamps 69 are not limited to the xenon flash lamps but may be krypton flash lamps.

The technique according to the present invention is also applicable to a heat treatment apparatus which comprises the light emitting part 5 including other types of lamps (e.g., halogen lamps) in place of the flash lamps 69 and which heats the semiconductor wafer W by light emission from the lamps.

While the hot plate 71 is used as the assist-heating element in the aforementioned preferred embodiment, a group of lamps (e.g., a plurality of halogen lamps) may be provided under the holding part 7 which holds the semiconductor wafer W to emit light therefrom, thereby achieving the assist-heating.

In the aforementioned preferred embodiment, the ion activation process is performed by exposing the semiconductor wafer to light. The substrate to be treated by the heat treatment apparatus according to the present invention is not limited to the semiconductor wafer. For example, the heat treatment apparatus according to the present invention may perform the heat treatment on a glass substrate formed with various silicon films including a silicon nitride film, a polycrystalline silicon film and the like. As an example, silicon ions are implanted into a polycrystalline silicon film formed on a glass substrate by a CVD process to form an amorphous silicon film, and a silicon oxide film serving as an anti-reflection film is formed on the amorphous silicon film. In this state, the heat treatment apparatus according to the present invention may expose the entire surface of the amorphous silicon film to light to polycrystallize the amorphous silicon film, thereby forming a polycrystalline silicon film.

Another modification may be made in a manner to be described below. A TFT substrate is prepared such that an underlying silicon oxide film and a polysilicon film produced by crystallizing amorphous silicon are formed on a glass substrate and the polysilicon film is doped with impurities such as phosphorus or boron. The heat treatment apparatus according to the present invention may expose the TFT substrate to light to activate the impurities implanted in the doping step.

While the invention has been described in detail, the foregoing description is in all aspects illustrative and not restrictive. It is understood that numerous other modifications and variations can be devised without departing from the scope of the invention.

What is claimed is:

1. A heat treatment apparatus for exposing a substrate to a flash of light to heat the substrate, comprising:
a light source including a plurality of flash lamps;
a chamber provided under said light source for receiving a substrate therein;
a holding element for holding the substrate within said chamber;
a plurality of gas outlets provided in a side wall surface of said chamber, said plurality of gas outlets being formed such that gas exhaust directions as viewed from said plurality of gas outlets are deviated at an equal angle from a central axis that passes through the center of said chamber in a vertical direction;
a gas supply for supplying an inert gas to said plurality of gas outlets;
an exhaust port provided in the vicinity of a central portion of a bottom surface of said chamber; and
an exhaust element for exhausting gas in said chamber through said exhaust port.

2. The heat treatment apparatus according to claim 1, wherein
a corner of the inner wall of said chamber is rounded.

3. The heat treatment apparatus according to claim 1, wherein
said plurality of gas outlets are formed such that the gas exhaust directions from said plurality of gas outlets are downward from a horizontal plane.

4. The heat treatment apparatus according to claim 1, wherein
said plurality of gas outlets are provided below said holding part.

5. The heat treatment apparatus according to claim 1, further comprising:
a controller for controlling said light source in such a manner that, while said plurality of gas outlets exhaust an inert gas discharged in said chamber from said exhaust port, said plurality of flash lamps emit a flash of light with no wafer held on said holding part.

6. A heat treatment apparatus for exposing a substrate to a flash of light to heat the substrate, comprising:
a light source including a plurality of flash lamps;
a chamber provided under said light source for receiving a substrate therein;
a holding element for holding the substrate within said chamber;
a plurality of gas outlets provided in a side wall surface of said chamber, said plurality of gas outlets being formed such that an inert gas discharged from said plurality of gas outlets forms a tornado-like flow in said chamber;
a gas supply for supplying an inert gas to said plurality of gas outlets;
an exhaust port provided in the vicinity of a central portion of a bottom surface of said chamber; and
an exhaust element for exhausting gas in said chamber through said exhaust port.
